(19) United States
(12) Patent Application Publication
(10) Pub. No.: US 2021/0181300 A1
(43) Pub. Date: Jun. 17, 2021

(54) PHASE SHIFTER GENERATING PULSE SIGNALS AND CONTINUOUS FREQUENCY SIGNALS, RADAR INCLUDING THE SAME, AND TRANSMITTER OF RADAR

(71) Applicant: Electronics and Telecommunications Research Institute, Daejeon (KR)

(72) Inventors: Jang Hong CHOI, Daejeon (KR); Bon Tae KOO, Daejeon (KR)

(73) Assignee: Electronics and Telecommunications Research Institute, Daejeon (KR)

(21) Appl. No.: 17/101,506

(22) Filed: Nov. 23, 2020

(30) Foreign Application Priority Data
Dec. 13, 2019 (KR) 10-2019-0166957
Sep. 15, 2020 (KR) 10-2020-0118159

(51) Int. Cl. G01S 7/282; G01S 7/03; H03L 7/081

(52) U.S. Cl. CPC G01S 7/282; H03L 7/0818; G01S 7/032

(57) ABSTRACT

Disclosed is a radar. The radar comprises a transmitter configured to radiate an output signal to an outside. The transmitter includes the phase shifter including a first oscillator configured to generate a first signal, based on a first external signal and a second oscillator configured to generate a second signal, based on a second external signal having a phase different from that of the first external signal, and wherein the first oscillator further receives the second signal to generate the first signal and the second oscillator further receives the first signal to generate the second signal, and configured to generate an oscillation signal of which phase is shifted based on the first signal and the second signal, and the signal amplifier configured to amplify the phase-shifted oscillation signal to generate the output signal.

### CROSS-REFERENCE TO RELATED APPLICATIONS

This application claims priority under 35 U.S.C. § 119 to Korean Patent Application No. 10-2019-0166957 filed on Dec. 13, 2019, and 10-2020-0118159, filed on Sep. 15, 2020, in the Korean Intellectual Property Office, the disclosures of which are incorporated by reference herein in their entireties.

### BACKGROUND

Embodiments of the inventive concept described herein relate to a phase shifter required for beamforming of a radar, and more particularly, relate to a radar including a phase shifter having an injection locked oscillator.

Recently developed radars are being developed in a form that may use various types of radar signals depending on user settings in various operating environments.

However, in the case of generating a signal of which phase is shifted using an injection locked oscillator in a conventional radar, there is a problem in that it is difficult to process an input signal, and there is a technical problem in generating various signals.

### SUMMARY

Embodiments of the inventive concept provide a phase shifter that generates a phase-shifted signal using an injection locked oscillator, and a radar including the same.

In addition, embodiments of the inventive concept provide a phase shifter that generates various signals in a pulse mode or a continuous frequency mode (CW mode) depending on a user's setting, and a radar including the same.

According to an embodiment of the inventive concept, a radar includes a phase shifter including a first oscillator that receives an external signal that is a basis for generating an oscillation signal and generates a first signal, and a second oscillator that generates a second signal, and that crosses and adds a gain of the first signal and a gain of the second signal and generates an oscillation signal of which phase is shifted, and the oscillation signal is operated in one of a first mode as a pulse signal or a second mode as a frequency continuous wave, a signal amplifier that amplifies a phase-shifted oscillation signal to generate an output signal, a transmitter including the phase shifter and the signal amplifier, and that radiates the output signal to an outside, a receiver that receives a signal from the outside, and a controller that receives a control mode signal corresponding to one of the first mode and the second mode, controls power supplied to the transmitter, based on the received signal, and transmits a frequency tuning signal to the phase shifter, based on the received signal.

According to an embodiment, when the control mode signal corresponds to the first operation mode, the controller may control a power supply of the phase shifter and the signal amplifier, based on a preset reference, may transmit a frequency lock code to the phase shifter during a duty cycle, and the transmitter may generate the output signal having the same waveform as the oscillation signal.

According to an embodiment, when the control mode signal corresponds to the first operation mode, the controller may control a power supply of the phase shifter and the signal amplifier, based on a preset reference, and may transmit a frequency free running code to the phase shifter in a section other than a duty cycle, and the transmitter may stop the output signal from being output.

According to an embodiment, when the control mode signal corresponds to the second operation mode, the controller always may supply the power to the transmitter and may control a capacitance value of the phase shifter.

According to an embodiment, the controller may transmit a frequency lock code to the phase shifter in all sections, and the transmitter continuously may generate the output signal.

According to an embodiment, the radar may further include an input device that receives a command corresponding to the first operation mode or the second operation mode, and the controller may determine the operation modes, based on the command.

According to an embodiment, the receiver may include a low pass filter that filters the received signal.

According to an embodiment, the controller may transmit a BW (band width) control signal to the receiver, and the low pass filter may determine a cutoff frequency, based on the BW control signal.

According to another embodiment of the inventive concept, a transmitter of a radar includes a phase shifter including a first oscillator that receives an external signal that is a basis for generating an oscillation signal and generates a first signal, and a second oscillator that generates a second signal, and that crosses and adds a gain of the first signal and a gain of the second signal and generates an oscillation signal of which phase is shifted, and the oscillation signal is operated in one of a first mode as a pulse signal or a second mode as a frequency continuous wave and a signal amplifier that amplifies the phase-shifted oscillation signal to generate an output signal.

According to an embodiment, the phase shifter may receive a control mode signal from a controller, and when the input control mode signal corresponds to a first mode, the phase shifter may generate a signal having the same frequency as the external signal during a duty cycle of the control mode signal.

According to an embodiment, the phase shifter may receive a control mode signal from a controller, and when the control mode signal corresponds to a first mode, the phase shifter may generate a signal corresponding to a frequency free running code in a section other than a duty cycle.

According to an embodiment, the phase shifter may receive a control mode signal from a controller, and when the control mode signal corresponds to a second mode, the phase shifter may always keep power in an ON mode and may change a capacitance value to generate a signal synchronized with a frequency of the input external signal.

According to an embodiment, the phase shifter may continuously generate the output signal in all sections.

According to an embodiment, the phase shifter may generate a signal corresponding to a first mode or a second mode, based on a command of a user.

According to another embodiment of the inventive concept, a phase shifter includes a 90 degree phase shifter that receives an external signal that is a basis for generating an oscillation signal, quadrature injection locked oscillators including a first oscillator that receives the external signal and generates a first signal and a second oscillator that generates a second signal, and that cross and add a gain of the first signal and a gain of the second signal and generates an oscillation signal of which phase is shifted, and the oscillation signal is operated in one of a first mode as a pulse signal or a second mode as a frequency continuous wave, and a quadrant phase selector that selects one of outputs of the quadrature injection locked oscillators.

### BRIEF DESCRIPTION OF THE FIGURES

The above and other objects and features of the inventive concept will become apparent by describing in detail exemplary embodiments thereof with reference to the accompanying drawings.

FIG. 1 is a diagram illustrating a configuration of a radar according to an embodiment of the inventive concept.

FIG. 2 is a diagram illustrating a configuration of a transmitter according to an embodiment of the inventive concept.

FIG. 3 is a diagram illustrating a phase shifter according to an embodiment of the inventive concept.

FIG. 4 is a diagram illustrating a circuit of an oscillator according to an embodiment of the inventive concept.

FIG. 5 is a diagram illustrating a configuration of a receiver according to an embodiment of the inventive concept.

FIG. 6 is a diagram illustrating a configuration of a controller according to an embodiment of the inventive concept.

FIG. 7 is a diagram illustrating a waveform of an output signal according to a pulse mode of the inventive concept.

FIG. 8 is a diagram illustrating a frequency domain of a received signal of the inventive concept.

FIG. 9 is a diagram illustrating a capacitor circuit included in a phase shifter according to an embodiment of the inventive concept.

FIG. 10 is a flowchart illustrating a process of controlling a radar in a pulse mode by a controller according to an embodiment of the inventive concept.

FIG. 11 is a flowchart illustrating a process of controlling a radar in a continuous frequency mode (CW mode) by a controller according to an embodiment of the inventive concept.

### DETAILED DESCRIPTION

Throughout the specification, the same reference numerals refer to the same components. This specification does not describe all elements of the embodiments, and overlaps between general contents or embodiments in the technical field to which the inventive concept pertains are omitted. The term “unit, module, member, or block” used in the specification may be implemented by software or hardware, and according to embodiments, it is also possible that a plurality of “unit, module, member, or block” may be implemented as one component, or that one “part, module, member, or block” includes a plurality of components.

Throughout the specification, when a part is “connected” to another part, this includes a case of being directly connected as well as being connected indirectly, and indirect connection includes connecting through a wireless communication network.

Also, when a part is said to “comprise” a certain component, this means that other components may be further included instead of excluding other components unless specifically stated otherwise.

Throughout the specification, when one member is positioned “on” another member, this includes not only the case where one member abuts another member, but also another member presents between the two members.

Terms such as first and second are used to distinguish one component from other components, and the component is not limited by the above-described terms.

A singular expression includes a plural expression unless the context clearly has an exception.

In each of steps, an identification code is used for convenience of description, and the identification code does not describe the order of each of the steps, and each of the steps may be performed differently from the specified order, unless a specific order is explicitly stated in the context.

Hereinafter, the principle and embodiments of the inventive concept will be described with reference to accompanying drawings.

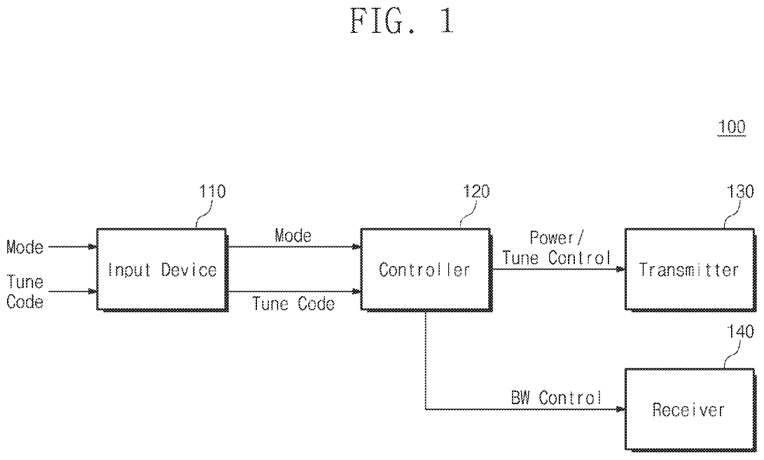

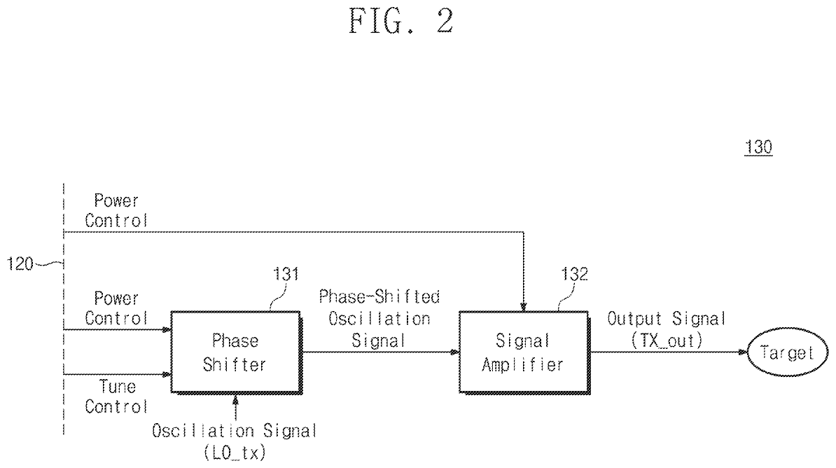

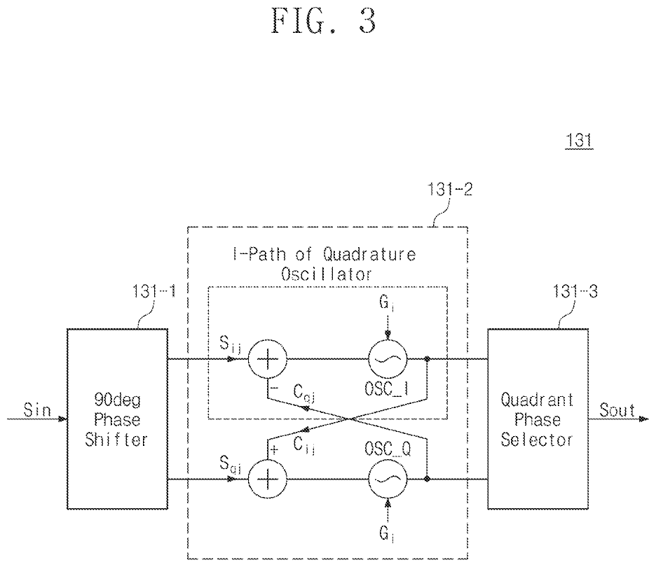

FIG. 1 illustrates a configuration of a radar 100 according to an embodiment of the inventive concept, FIG. 2 illustrates a configuration of a transmitter 130 according to an embodiment of the inventive concept, and FIG. 3 illustrates a phase shifter according to an embodiment of the inventive concept.

Referring to FIG. 1, the radar 100 according to an embodiment of the inventive concept includes a controller 120, the transmitter 130, and a receiver 140, and may include an input device 110.

The input device 110 receives a command and a frequency tune code corresponding to a control mode of the radar 100 from a user, and transmits the input command and the frequency tune code to the controller 120.

The controller 120 receives the command and the frequency tune code corresponding to the control mode of the radar 100 from the input device 110, and controls the transmitter 130 and the receiver 140, based on the command and the frequency tune code corresponding to the control mode of the radar 100. In more detail, the control mode may be classified into a first mode or a second mode. The first mode refers to a pulse mode in which an oscillation signal is a pulse waveform signal and the radar 100 radiates the pulse waveform signal. The second mode refers to a continuous wave (CW) mode in which the oscillation signal is a frequency continuous wave and the radar 100 radiates the frequency continuous wave. In addition, the controller 120 may receive a signal corresponding to the first mode or the second mode, may control power supplied to the transmitter 130 based on the input signal, and may transmit a frequency tuning signal to a phase shifter 131, based on the input signal. A control process of the controller 120 will be described in detail below while describing operations of the transmitter 130 and the receiver 140.

Referring to FIGS. 1, 2, and 3, the transmitter 130 includes the phase shifter 131 and a signal amplifier 132. In addition, the phase shifter 131 includes a 90 degree phase shifter 131-1, quadrature injection locked oscillators 131-2, and a quadrant phase selector 131-3.

The 90 degree phase shifter 131-1 receives a signal Sin, which is a basis for generating an oscillation signal, from an outside, branches the input external signal into I/Q signals to input the input external signal to each I/Q path of the quadrature injection locked oscillators 131-2. When the branched I/Q signals (Sij, Sqj) are input to the quadrature injection locked oscillators 131-2 and a frequency and a magnitude of the input oscillation signal satisfy a frequency locking condition, the quadrature injection locked oscillators 131-2 synchronize an output signal with the frequency of the input oscillation signal, and maintains the frequency of the output signal in a locked state. In this case, the frequency locked state means a state in which a frequency is maintained in a uniform waveform.

The quadrature injection locked oscillators 131-2 include a first oscillator generating a first signal and a second oscillator generating a second signal, and allow the oscillators to generate an oscillation frequency. In this case, each of the oscillators is configured to generate an injection locking based frequency with each other. In addition, the quadrature injection locked oscillators 131-2 may cross and add gains of a first signal Cqj and a second signal Cij, and may generate phase-shifted oscillation signals in which phases of the quadrature injection locked oscillators 131-2 are adjusted. In this case, a stable variable phase change range of each output of the quadrature injection locked oscillators 131-2 has a value of approximately 90 degrees, but the inventive concept is not limited thereto.

The quadrant phase selector 131-3 selects one of the outputs of the quadrature injection locked oscillators 131-2 with differential structure, outputs the oscillation signal of which phase is shifted, and transmits the output signal to the signal amplifier 132. In this case, there may be four output signals of the quadrature injection locked oscillators 131-2.

The signal amplifier 132 amplifies the oscillation signal of which phase is shifted to generate an output signal.

The transmitter 130 radiates the output signal generated while the oscillation signal passes through the phase shifter 131 and the signal amplifier 132 to the outside.

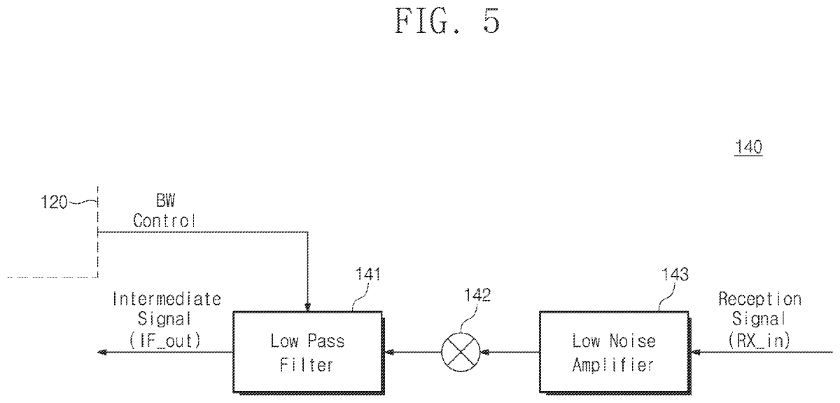

The receiver 140 receives a signal from the outside and filters the received signal. The receiver 140 may include a low pass filter 141, a mixer 142, and a low noise amplifier 143, and may determine a cutoff frequency of the received signal. A detailed configuration of the receiver 140 will be described later in FIG. 5.

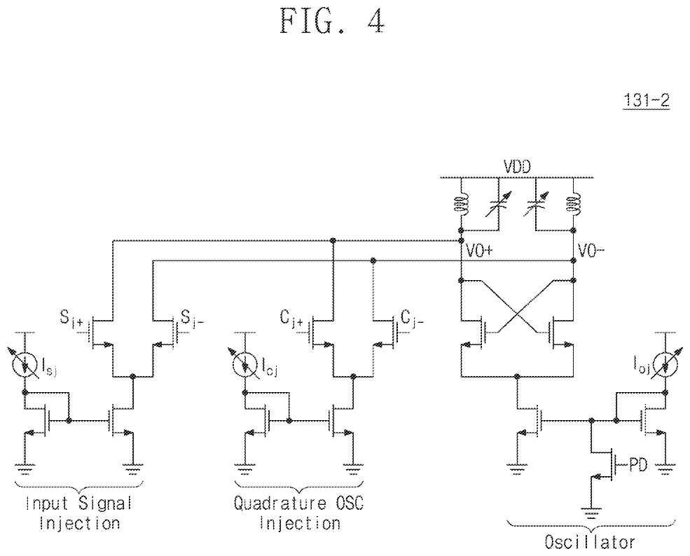

FIG. 4 illustrates a circuit of the quadrature injection locked oscillators 131-2 according to an embodiment of the inventive concept.

Referring to FIG. 4, the quadrature injection locked oscillators 131-2 according to the inventive concept include an input signal injector, a quadrature OSC injector, and an oscillator.

In this case, the gain of the first signal Cqj may be implemented by varying a current Icj of a current source of the Quadrature OSC injector. In this case, Sj+ and Sj− of the input signal injector may be provided from the 90 degree phase shifter 131-1. In addition. Cj+ and Cj− of the quadrature OSC injector may be output signals of a Q-path side ILO of the quadrature injection locked oscillators 131-2. In addition, to change an output phase of the quadrature injection locked oscillators 131-2, a current source Ioj of the oscillator, a current source Icj of the quadrature OSC injector, and a current source Isj of the input signal injector may be adjusted.

FIG. 5 illustrates a configuration of the receiver 140 according to an embodiment of the inventive concept.

As described above, the receiver 140 receives the signal from the outside and filters the received signal. The receiver 140 may include the low pass filter 141, the mixer 142, and the low noise amplifier 143, and may determine the cutoff frequency of the received signal.

In more detail, the signal received from the outside is amplified by passing through the low noise amplifier 143, is passed through the mixer 142, and is input to the low pass filter 141. In this case, the receiver 140 cancels components other than the cutoff frequency from a reception signal RX_in and outputs an intermediate signal if_out. In this case, the cutoff frequency is determined based on a band width (BW) control signal received from the controller 120. Specifically, since a signal band width to be output from the receiver 140 is different depending on a radar control mode, it is necessary to set the cutoff frequency of the low pass filter 141 differently. The BW control signal is a signal that sets an appropriate bandwidth of signals for each mode and determines the cutoff frequency of the low pass filter 141.

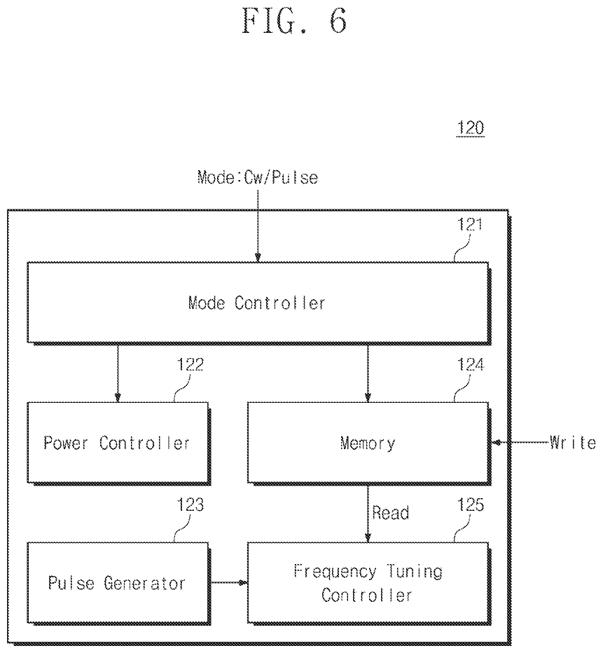

FIG. 6 illustrates a configuration of the controller 120 according to an embodiment of the inventive concept.

The controller 120 according to the inventive concept may include a mode controller 121, a power controller 122, a pulse generator 123, a memory 124, and a frequency tuning controller 125.

The mode controller 121 receives an input signal corresponding to the pulse mode or the continuous frequency mode and controls the power controller 122, the pulse generator 123, or the memory 124.

In more detail, when the radar 100 is controlled in the pulse mode, the mode controller 121 transmits a power control signal to the power controller 122 during a section in which a pulse signal is generated, and cuts off power of the transmitter 130 while the pulse signal is not generated. In addition, when the radar 100 is controlled in the pulse mode, since a setting time is required for the signal amplifier 132 to operate normally, the mode controller 121 transmits a control signal to supply power to the signal amplifier 132 in advance such that the signal amplifier 132 operates stably. However, when the radar 100 is controlled in the continuous frequency mode, the mode controller 121 always transmits the power control signal to the power controller 122, and always keeps the power of the transmitter 130 in ON state.

When the power is supplied to the power controller 122, the pulse generator 123 generates a pulse and causes the transmitter 130 to generate a pulse signal.

The memory 124 stores a lock code and a free running code during the initialization process of the transmitter 130. In this case, the lock code refers to a code corresponding to a lock frequency of the signal generated from the transmitter 130, and the free running code refers to a code corresponding to a frequency generated while no pulse signal is generated.

The frequency tuning controller 125 receives information about the lock code and the free running code from the memory 124, and allows the transmitter 130 to generate the signal, based on the input information. As a result, the transmitter 130 may generate the output signal by adjusting a capacitance of the quadrature injection locked oscillators 131-2 while the pulse is generated in the pulse mode. Also, the transmitter 130 may generate the output signal by always adjusting the capacitance of the quadrature injection locked oscillators 131-2 in the continuous frequency mode.

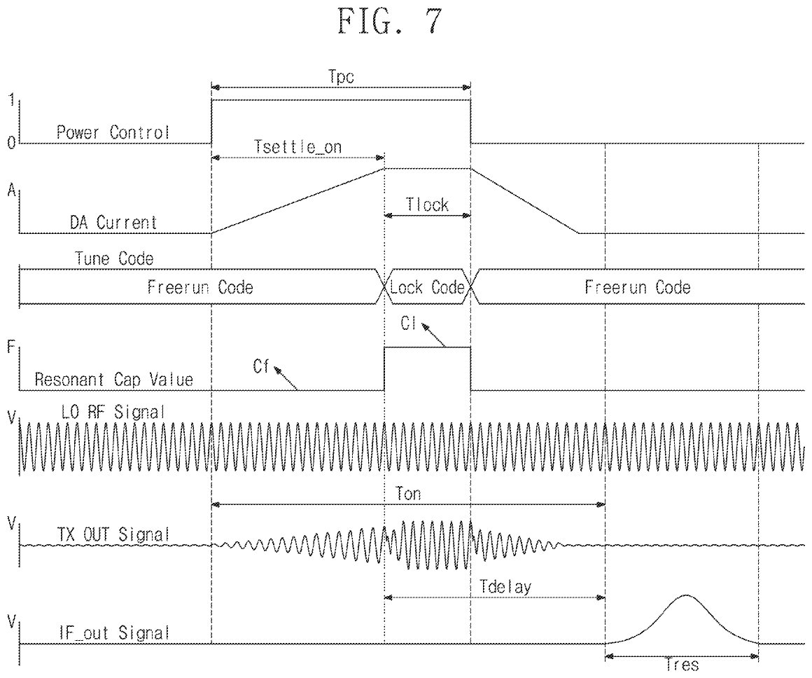

FIG. 7 illustrates a waveform of an output signal according to a pulse mode of the inventive concept.

Referring to FIG. 7, an external signal (Lo RF Signal) input while the radar 100 is operating is always input. As described above, the controller 120 controls a power supply of the transmitter 130 and allows the transmitter 130 to generate the signal, based on the frequency tune code.

In more detail, when the radar 100 is controlled in the pulse mode, the power control is performed by the controller 120 supplying power to the transmitter 130 (Tpc) and the signal amplifier 132 entering a normal operation section (Tlock) through a setting time (Tsettle_On). In addition, when the signal amplifier 132 enters the normal operation section (Tlock), the frequency tuning controller 125 transmits the free running code and then transmits the lock code to the transmitter 130. As a result, when the power control starts, an output signal (TX_OUT Signal) gradually changes from a waveform corresponding to the free running code to a waveform corresponding to the lock code, and when the signal amplifier 132 enters the normal operating section (Tock), the transmitter 130 generates the output signal having a frequency corresponding to the lock code. In addition, when the output signal is reflected to the target and is input to the receiver 140, the receiver 140 may generate a signal having a waveform corresponding to a reception signal Tres while generating the intermediate signal (IF_out signal). When the normal operation section (Tlock) of the signal amplifier 132 ends, the transmitter 130 generates a signal corresponding to the free running code again through a delay section Tdelay.

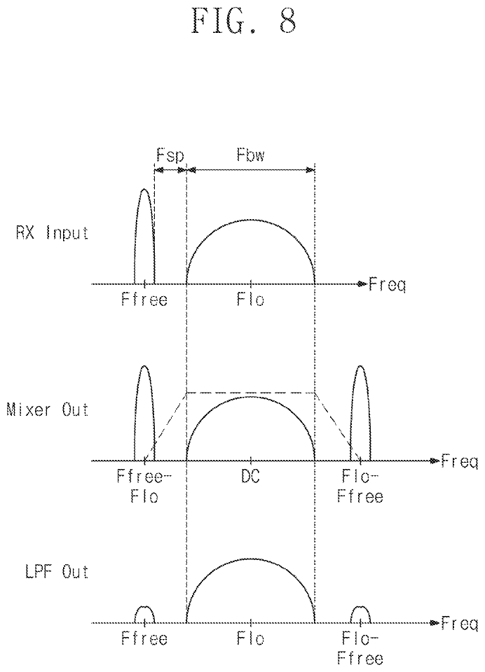

FIG. 8 illustrates a frequency domain of a received signal of the inventive concept.

Referring to FIG. 8, the reception signal RX_in input to the receiver 140 is a signal reflected by the target and is composed of spectral components having a free frequency Ffree and a reflection frequency Flo. In this case, the free frequency Ffree means a reception frequency component related to a signal generated by the free running code of the transmitter 130, and the reflection frequency Flo means a reception frequency related to a signal generated by the lock code of the transmitter 130. The free frequency Ffree and the reflection frequency Flo are mixed in the mixer 142, and the reflection frequency Flo is shifted to a frequency (a DC frequency) having the same magnitude due to a mixing effect. In this case, the low pass filter 141 cancels a component of the free frequency from the reflection frequency based on the free running frequency, and restores the pulse signal Fbw of which band width is adjusted.

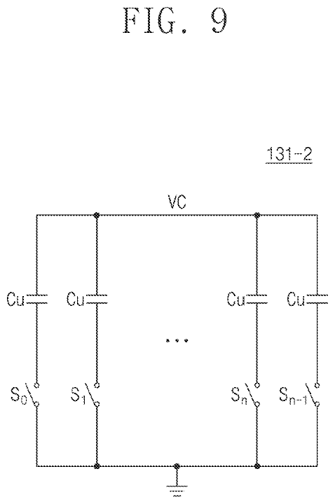

FIG. 9 illustrates a capacitor circuit included in the phase shifter 131 according to an embodiment of the inventive concept.

Referring to FIG. 9, the phase shifter 131 according to the inventive concept includes a plurality of capacitors Cu and switching circuits S0 to Sn-1. When the power control signal and the frequency tuning signal are input from the controller 120, the phase shifter 131 controls on/off of switches connected to a plurality of capacitors, and consequently controls the capacitance of the phase shifter 131 to generate the phase-shifted oscillation signal.

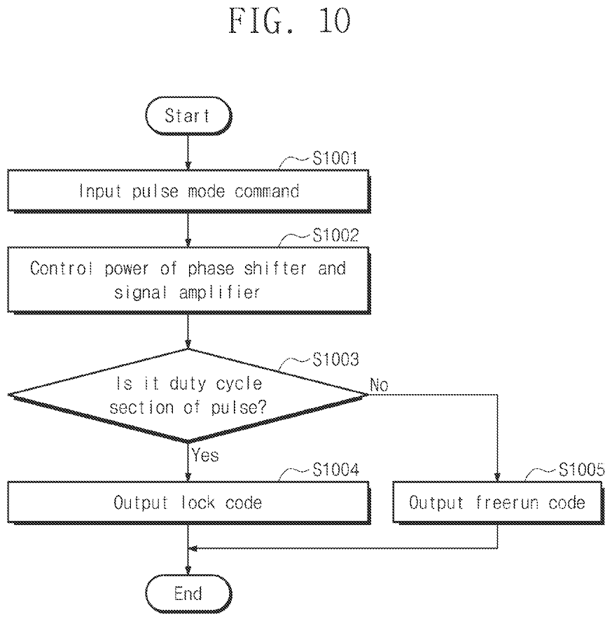

FIG. 10 illustrates a process of controlling the radar 100 in a pulse mode by the controller 120 according to an embodiment of the inventive concept.

Referring to FIG. 10, when the user inputs a pulse mode command to the input device 110, the radar 100 is controlled in the pulse mode (S1001).

When the radar 100 starts to be controlled in the pulse mode, the controller 120 controls power supplied to the phase shifter 131 and the signal amplifier 132 (S1002). As described above, when power control is started, the controller 120 supplies power to the transmitter 130 (Tpc), and the signal amplifier 132 passes through the setting time (Tsettle_On) and then enters the normal operation section (Tlock).

When power supplied to the phase shifter 131 and the signal amplifier 132 is controlled, the controller 120 determines whether the pulse section is a duty cycle section (S1003).

When it is determined that the pulse section is the duty cycle section, the controller 120 outputs the frequency lock code (S1004), and controls the transmitter 130 to generate the output signal. When it is determined that the pulse section is not the duty cycle section, the controller 120 outputs the free running code (S1005), and the transmitter 130 does not generate the output signal.

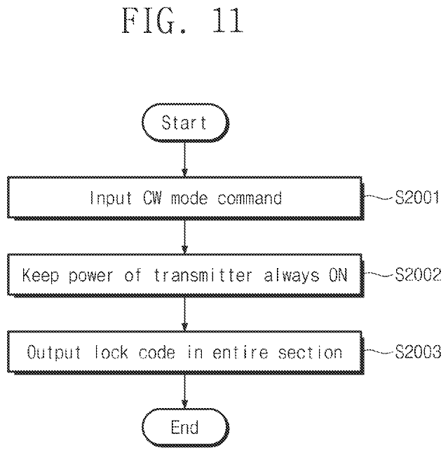

FIG. 11 illustrates a process of controlling the radar 100 in a continuous frequency mode (CW mode) by the controller 120 according to an embodiment of the inventive concept.

Referring to FIG. 11, when the user inputs a continuous frequency mode command to the input device 110, the radar 100 is controlled in the continuous frequency mode (S2001).

When the radar 100 is controlled in the continuous frequency mode, the controller 120 supplies power to the transmitter 130 such that the power of the transmitter 130 is always in ON mode (S2002).

When power is always supplied to the transmitter 130, the controller 120 controls the transmitter 130 to output the output signal in an entire section (S2003).

An embodiment of the inventive concept may provide a phase shifter that generates a phase-shifted signal using a quadrature injection locked oscillator, and a radar including the same.

In addition, an embodiment of the inventive concept may provide a phase shifter that generates various signals in a pulse mode or a continuous frequency mode (CW mode) depending on a user's setting, and a radar including the same.

The contents described above are specific embodiments for implementing the inventive concept. The inventive concept may include not only the embodiments described above but also embodiments in which a design is simply or easily capable of being changed. In addition, the inventive concept may also include technologies easily changed to be implemented using embodiments.

What is claimed is:

1. A radar comprising:
a transmitter including a phase shifter and a signal amplifier, and configured to radiate an output signal to an outside;
a receiver configured to receive a signal reflected from a target by the output signal; and
a controller configured to control an operation mode of the phase shifter, and
wherein the transmitter includes:
the phase shifter including a first oscillator configured to generate a first signal, based on a first external signal and a second oscillator configured to generate a second signal, based on a second external signal having a phase different from that of the first external signal, and wherein the first oscillator further receives the second signal to generate the first signal and the second oscillator further receives the first signal to generate the second signal, and configured to generate an oscillation signal of which phase is shifted based on the first signal and the second signal; and
the signal amplifier configured to amplify the phase-shifted oscillation signal to generate the output signal,
wherein the phase shifter outputs the oscillation signal as a pulse signal in a first operation mode under a control of the controller, and outputs the oscillation signal as a frequency continuous wave in a second operation mode, and
wherein the controller receives a control mode signal corresponding to one of the first operation mode and the second operation mode, controls power supplied to the transmitter, based on the received signal, and transmits a frequency tuning signal for controlling the operation mode of the phase shifter, based on the received signal.

2. The radar of claim 1, wherein, when the control mode signal corresponds to the first operation mode, the controller controls a power supply of the phase shifter and the signal amplifier, based on a preset reference, and transmits a frequency lock code to the phase shifter during a duty cycle, and
wherein the transmitter generates the output signal having the same waveform as the oscillation signal.

3. The radar of claim 1, wherein, when the control mode signal corresponds to the first operation mode, the controller controls a power supply of the phase shifter and the signal amplifier, based on a preset reference, transmits a frequency free running code to the phase shifter in a section other than a duty cycle, and
wherein the transmitter stops the output signal from being output.

4. The radar of claim 1, wherein, when the control mode signal corresponds to the second operation mode, the controller always supplies the power to the transmitter and controls a capacitance value of the phase shifter.

5. The radar of claim 4, wherein the controller transmits a frequency lock code to the phase shifter in all sections, and
wherein the transmitter continuously generates the output signal.

6. The radar of claim 1, further comprising:
an input device configured to receive a command corresponding to the first operation mode or the second operation mode, and
wherein the controller determines the operation mode, based on the command.

7. The radar of claim 1, wherein the receiver includes a low pass filter configured to filter the received signal.

8. The radar of claim 6, wherein the controller transmits a BW (band width) control signal to the receiver, and
wherein a low pass filter determines a cutoff frequency, based on the BW control signal.

9. A transmitter of a radar comprising:
a phase shifter including a first oscillator configured to generate a first signal, based on a first external signal and a second oscillator configured to generate a second signal, based on a second external signal having a phase different from that of the first external signal, and wherein the first oscillator further receives the second signal to generate the first signal and the second oscillator further receives the first signal to generate the second signal, and configured to generate an oscillation signal of which phase is shifted based on the first signal and the second signal; and
a signal amplifier configured to amplify the phase-shifted oscillation signal to generate an output signal.

10. The transmitter of a radar of claim 9, wherein the phase shifter receives a control mode signal from a controller, and
wherein, when the input control mode signal corresponds to a first mode, the phase shifter generates a signal having the same frequency as first external signal during a duty cycle of the control mode signal.

11. The transmitter of a radar of claim 9, wherein the phase shifter receives a control mode signal from a controller, and
wherein, when the control mode signal corresponds to a first mode, the phase shifter generates a signal corresponding to a frequency free running code in a section other than a duty cycle.

12. The transmitter of a radar of claim 9, wherein the phase shifter receives a control mode signal from a controller, and
wherein, when the control mode signal corresponds to a second mode, the phase shifter always keeps power in an ON mode and changes a capacitance value to generate a signal synchronized with a frequency of the first external signal.

13. The transmitter of a radar of claim 12, wherein the phase shifter continuously generates the output signal in all sections.

14. The transmitter of a radar of claim 9, wherein the phase shifter generates a signal corresponding to a first mode or a second mode, based on a command of a user.

15. A phase shifter comprising:
a 90 degree phase shifter configured to receive an external signal that is a basis for generating an oscillation signal;
quadrature injection locked oscillators including a first oscillator configured to generate a first signal, based on a first external signal and a second oscillator configured to generate a second signal, based on a second external signal having a phase different from that of the first external signal, and wherein the first oscillator further receives the second signal to generate the first signal and the second oscillator further receives the first signal to generate the second signal, and configured to generate an oscillation signal of which phase is shifted based on the first signal and the second signal, and
a quadrant phase selector configured to select one of outputs of the quadrature injection locked oscillators.
